(19) United States
(12) Patent Application Publication
(10) Pub. No.: US 2014/0291289 A1
(43) Pub. Date: Oct. 2, 2014

(54) METHOD FOR ETCHING POROUS ORGANOSILICA LOW-K MATERIALS

(71) Applicant: TOKYO ELECTRON LIMITED, Tokyo (JP)

(72) Inventors: Frederic LAZZARINO, Leuven (BE); Shigeru TAHARA, Miyagi (JP); Mikhail KRISHTAB, Leuven (BE); Mikhail BAKLANOV, Leuven (BE)

(73) Assignee: TOKYO ELECTRON LIMITED, Tokyo (JP)

(21) Appl. No.: 14/225,107

(22) Filed: Mar. 25, 2014

(30) Foreign Application Priority Data
Mar. 26, 2013 (EP) 13160988

(51) Int. Cl. H01L 21/768

(52) U.S. Cl. CPC H01L 21/76802
USPC 216/67

(57) ABSTRACT

A method of etching a low-k material which is capable of decreasing a damage of the low-k material is provided. In the method, the low-k material is etched with a plasma of a mixture gas including NF₃ gas and Cl₂ gas. Utilization of the mixture gas enables to decrease a damage of the low-k material, enhance an etch rate and selectivity of the low-k material, and reduce the bottom surface roughness and water absorption of the low-k material.

### CROSS-REFERENCES TO RELATED APPLICATIONS

The present invention claims priority of European Patent Application No. 13160988 filed on Mar. 26, 2013, the entire contents of which are incorporated herein by reference.

### TECHNICAL FIELD

The present disclosure relates to methods for etching porous organosilica low-k materials.

### BACKGROUND OF THE DISCLOSURE

The continuous decrease in the critical dimensions (CD) of advanced BEOL interconnect technology node and the introduction of advanced dielectric materials with k-value below 2.5 have made the use of plasma etching increasingly challenging.

Integration of advanced low-k materials into dual-damascene structure with ever-shrinking critical dimensions (CD) imposes tight restrictions on the thicknesses of auxiliary layers such as hard masks and barrier films as well as acceptable level of low-k dielectric damage caused by etching plasma.

Indeed, besides the morphological aspects, such as the profile of the structure into the low-k material, bottom roughness and residue, the degradation of the dielectric properties of the low-k material is another important aspect that needs to be understood and well-controlled.

As plasma etch has been identified to be the main contributor for low-k damage, it is therefore important to develop chemistries that induce limited damages into the low-k while providing good patterning capabilities.

### SUMMARY OF THE DISCLOSURE

It is an aim of this disclosure to present a plasma etch method that eliminates or minimizes the damage induced into the porous organosilicate porous low-k materials during plasma etching.

This aim is achieved by using a non-polymerizing NF₃ plasma chemistry (carbon-free) that does not rely on a polymer layer (CFx fluorocarbon layer) to passivate the sidewall of the low-k material for obtaining a well-controlled profile of the structure. The use of a carbon free chemistry has a further advantage in that it eliminates the need for applying a post etch residue cleaning step, thereby further reducing the damage of the porous organosilica low-k material.

It is another aim of this disclosure to reduce the bottom surface roughness and water absorption of organisilica porous low-k material. This aim has been achieved by introducing in the non-polymerizing NF₃ plasma chemistry a small amount (>1 sccm) of Cl₂. The introduction of Cl₂ in the NF₃ based plasma has a further advantage in that it improves the etching plasma selectivity to the dielectric hard mask. It has also been shown that adding a small amount of Cl₂ improves low-k damage and water absorption when using usual fluorocarbon-based low-k chemistries.

### BRIEF DESCRIPTION OF THE DRAWINGS

All drawings are intended to illustrate some aspects and embodiments of the present disclosure. The drawings described are only schematic and are non-limiting.

FIG. 1 represents the effective thickness of damaged layer and etch rate for C₄F₈/Ar-based recipes.

FIG. 2 represents the etch rate for NF₃- and CF₄-based recipes.

FIG. 3 represents the effective thickness of damaged layer for NF₃- and CF₄-based recipes.

FIG. 4A shows L/S 60 nm/20 nm etched into 50 nm LK 2.3 using an oxide hard mask and FIG. 4B shows L/S 20 nm/20 nm etched into 50 nm LK 2.3 using an oxide hard mask.

FIG. 5A shows LK 2.3 pristine, FIG. 5B shows LK 2.3 after etching using NF₃-based chemistry, and FIG. 5C shows LK 2.3 after etching using NF₃-based chemistry with Cl₂ addition.

FIGS. 6A and 6B show the Normalized FUR spectra for NF₃-based recipes in two regions.

FIG. 7 describes exemplified recipe details of a non-polymerized NF₃ plasma chemistry.

FIG. 8 presents a method to calculate the equivalent thickness of damaged layer.

### DETAILED DESCRIPTION OF ILLUSTRATIVE EMBODIMENTS

The present disclosure relates to a method for etching porous organosilica materials. The method is suitable for etching porous organosilica materials such as ultra-low-κ dielectric materials, which are used in interconnect applications of advanced integrated circuits.

In general, a low-κ dielectric is a material with a small dielectric constant relative to silicon dioxide. Further an ultra-low κ dielectric material is characterized by a dielectric constant κ lower than 2.3, more preferably lower than 2.1. Usually the pore size of such a material is between 1 and 5 nm.

Etching of porous organosilica low-k materials using a traditional fluorocarbon based plasma may cause damage to the low-k material. This is due to the formation of a polymer layer (CFx fluorocarbon layer) on the low-k sidewall. On one hand, this layer prevents the low-k film from carbon depletion (loss of Si—CH₃ group) but on the other hand, this layer is also a source of fluorine radicals that can diffuse into the low-k and induce damage.

The use of a non-polymerizing NF₃ plasma chemistry (carbon-free) which does not rely on a polymer layer (CFx fluorocarbon layer) to passivate the sidewall of the low-k (profile control) has been shown to significantly reduce the damage of the porous organosilica low-k material.

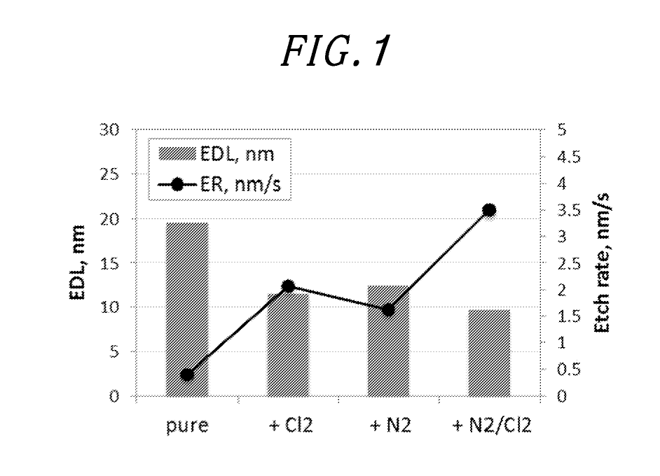

In experiments, a series of polymerizing C₄F₈-based plasma recipes were tested first to see the effect of nitrogen, argon and chlorine additives on the effective thickness of damaged layer and etch rate. According to the results presented in FIG. 1, the level of damage shows a clear dependency on the etch rate and can be attributed mainly to the diffusion of fluorine radicals from the intermixed SiOₓC_{y}F_{z} layer on top of the film. The lowest damage was observed for the recipe including both N₂ and Cl₂, but even for those the depth of damage was relatively high and approached 10 nm. One of the possible ways to improve the situation is to use a less or a non-polymerizing chemistry to optimize the etch rate as compared to damage diffusion.

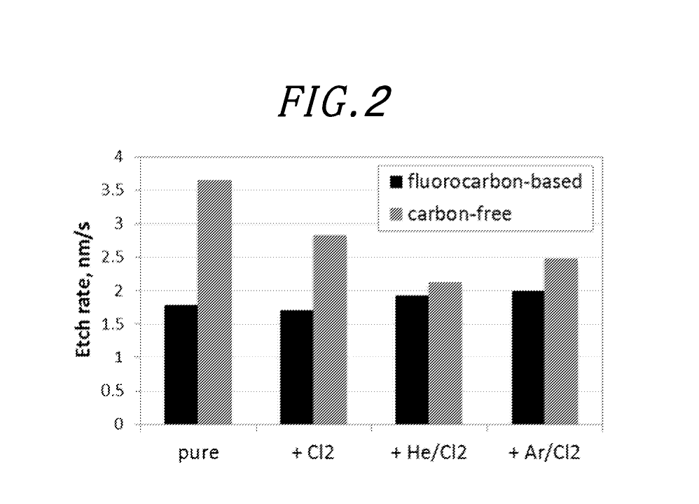

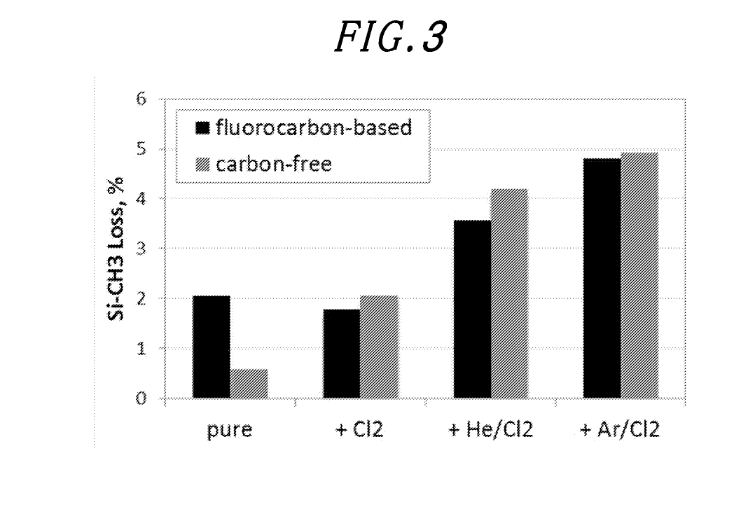

Indeed, the effect of a non-polymerizing NF₃ plasma was compared with the effect of a CF₄ discharge ignited at the same conditions. Being put in equal conditions, pure NF₃-plasma demonstrated higher etch rate of approximately 3.5 nm/s compared to other plasma gas mixtures, as shown in FIG. 2. This is because of the notably lower bond dissociation energy resulting in a higher concentration of radicals produced in the plasma. The absence of carbon coming from the NF₃-plasma decreased the Carbon/Fluorine ratio (C/F) at the low-k surface allowing further accelerating etch process, which leaves less time for the diffusion of active fluorine thereby positively impacting the low-k damage. As shown in FIG. 3, this resulted in an extremely thin carbon depleted layer of approximately 1 nm.

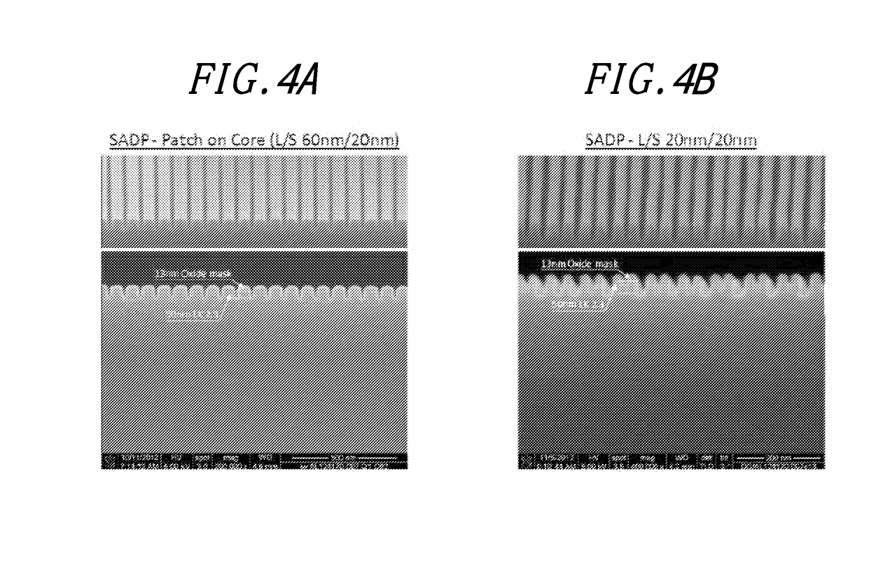

Moreover, the effective low-k material damage is further reduced with the use of a non-polymerizing plasma chemistry, such as NF₃. This is because such chemistries are free of oxygen, which may diffuse through the thin polymer layer and damage the low-k material below. From morphological point of view, the non-polymerizing NF₃ chemistry leads to straight profile (no undercut, no bowing) showing a good passivation of the low-k sidewalls, as shown in FIGS. 4A and 4B. The nitrogen coming from NF₃ reacts with the carbon (C) present in the low-k film to form a carbon nitride (CN) protective layer on top of the low-k sidewalls. As a result of the use of NF₃ chemistry, passivation of the sidewall and controlling the profile of the low-k structure does not require the addition of any further gases. The use of NF₃ chemistry eliminates the need for the addition of O₂ or N₂ required by the standard fluorocarbon chemistries, thereby minimizing the low-k damage caused by the addition of O₂.

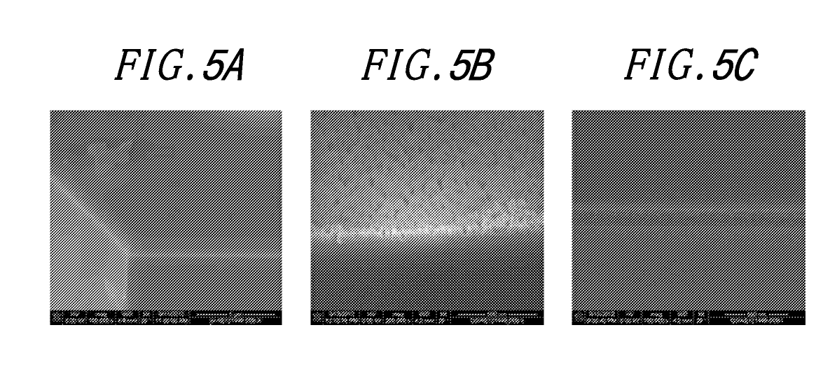

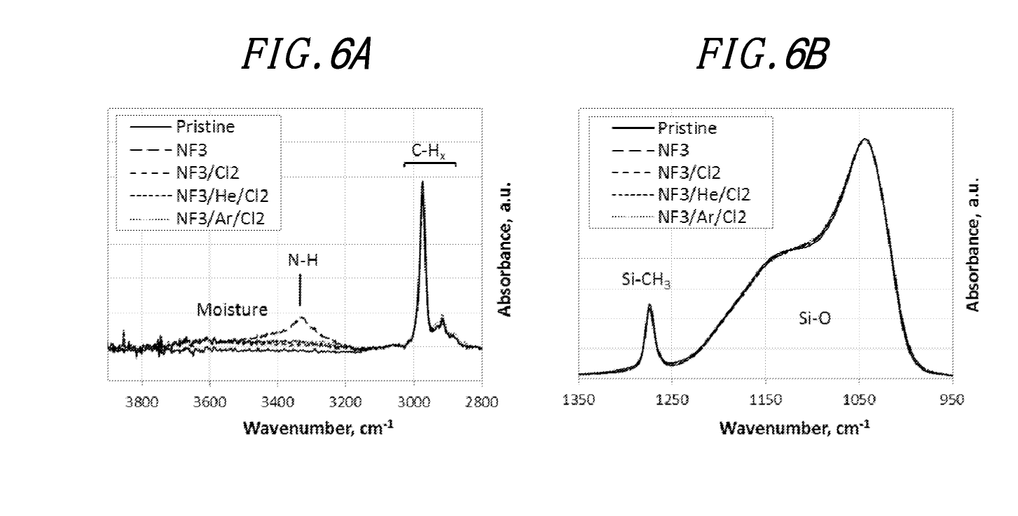

However, exposure of porous organosilica low-k materials to non-polymerizing NF₃ plasma also leads to incorporation of amino-groups, which is highly unfavorable because it leads to water absorption. Indeed, amino groups are formed on the low-k surface exposed to the non-polymerizing NF₃ plasma chemistry leading to a significant surface roughness, as shown in FIG. 5, and high water absorption as amino groups are polar as shown in FTIR spectrum in FIGS. 6A and 6B.

This issue has been solved by adding a small amount of chlorine (Cl₂) in the initial chemistry. However, the Cl₂ addition slightly decreases the etch rate of the porous organosilica low-k material to approximately 2.8n m/s and slightly degrades the dielectric properties of the film An equivalent damage layer of approximately 4 nm can be calculated from the values shown in FIG. 2 and FIG. 3. It has also been observed that the addition of Cl₂ in standard fluorocarbon-based chemistries may be used to reduce the effective damage layer (EDL) thickness from 20 nm to 10 nm, as shown in FIG. 1.

Although the presence of chlorine (Cl₂) in NF₃ plasma causes a slight drop in etch rate and embeds some additional damage, it imparts such an essential property to the etching plasma as selectivity to silica-based dielectric hard mask. Previous studies of NF₃/Cl₂-plasma revealed that the etching mechanism can be explained in terms of dissociative chemisorption of interhalogen ClFₓ moieties formed in the discharge. Unlike fluorocarbon-based plasma where actual etchant, i.e., CFₓ radicals, are supplied directly from plasma or top fluorocarbon polymer layer, in NF₃/Cl₂ plasma, active fluorine radicals are formed selectively on surfaces where energy of adsorption is enough for dissociation of interhalogen molecules. In turn, the heat of adsorption may depend on type of bonds constituting the surface and their ionicity, what leads to selective etching of organosilica layer featuring high concentration of Si—C over dielectric hard mask.

A further advantage of using a non-polymerizing NF₃ plasma is that it does not lead to the formation of the usual post-etch residue, such as fluorocarbon polymer like CFx. As a result, the post-etch clean step is significantly facilitated and, to some extent, can possibly be removed from the process flow

Etching experiments were carried out in a Vesta™ dual frequency CCP chamber manufactured by Tokyo Electron Limited. An inverse polarity de-chucking sequence was used in order to minimize the damage contribution from the dechuck step. All the tests were performed on coupons glued on 300 mm SiCN carrier wafers. Spectroscopic ellipsometer Sentech SE801 operating in the wavelength range 350-850 nm was used to estimate etch rates, by measuring thickness before and after plasma exposure. Evaluation of damage was done by means of FTIR spectroscopy, reflecting compositional modification of low-k film, mainly in the form of Si—CH₃ bonds cleavage and moisture uptake. To alleviate effect of different thickness values on FTIR spectra, an equivalent damage layer (EDL) was calculated based on the change of Si—CH₃ absorption peak area and thickness of resultant film. The dielectric constant was extracted from CV-curves at 100 kHz measured on Metal-Insulator-Semiconductor structures with platinum top contacts.

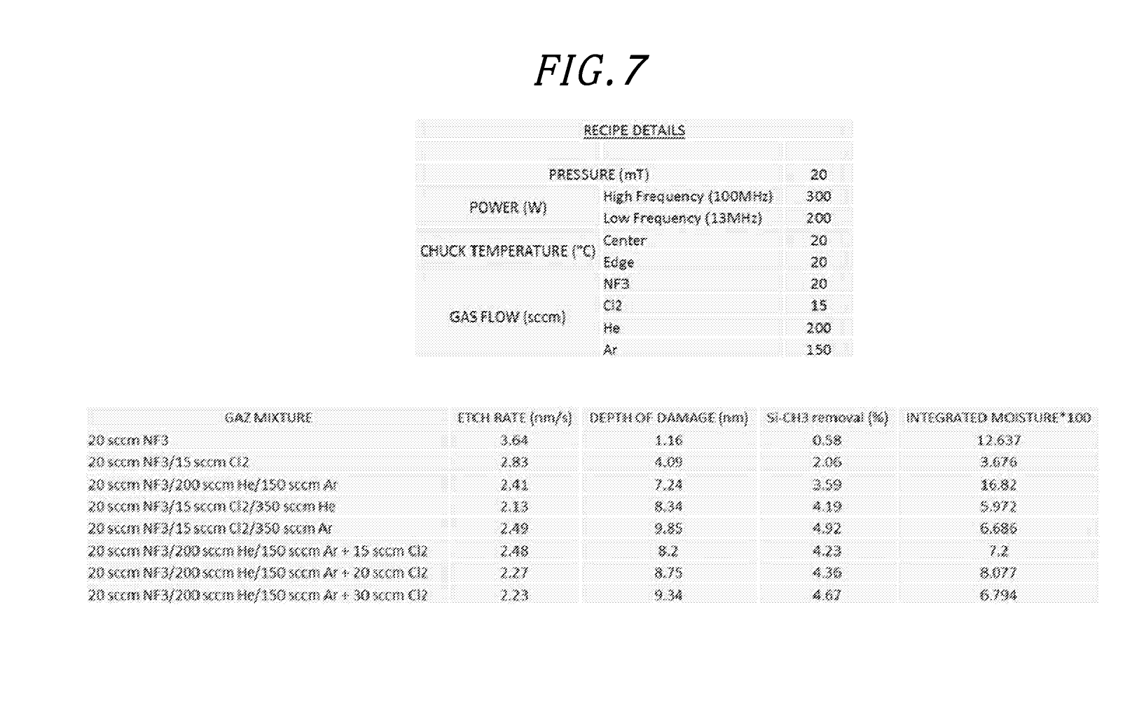

Exemplified recipe details of a non-polymerized NF₃ plasma chemistry are presented in FIG. 7. It should be noted that the values discussed are only representative and non-limited in any way.

In the recipe presented, NF₃ gas flow can vary between 5 sccm and 50 sccm. It should be considered that increasing NF₃ will negatively impact the EDL due to the increase of fluorine radicals in the plasma. Although NF₃ is the preferred gas mixture, other gas mixtures may also be considered such as SiF4.

Cl₂ gas flow can vary between 0 sccm and 50 sccm. The addition of Cl₂ will slightly impact the effective damage layer thickness (EDL), which may vary from 1 up to 4 nm for NF₃/Cl₂ and from 7 nm up to 9 nm for NF₃/Cl₂/He/Ar. However, it also significantly decreases the moisture uptake and improve the roughness of the etch front. It also help to better control the etch process as adding Cl₂ will slightly decrease the low-k etch rate. Depending on low-k film properties, Cl₂ can vary between 0 sccm and 50 sccm in the etch process. Although Cl₂ is a preferred gas mixture to be added to the NF₃ plasma chemistry it can possibly be replaced by other Clx-containing gas such like BCl₃ or SiCl₄.

He and Ar may be used to dilute the chemistry and to get better control of the etch rate. Indeed, if He flow and/or Ar flow increase then the etch rate of the low-k decreases while slightly increasing the EDL from 4 nm up to 9 nm on blanket wafers. This increase of the low-k damage is most probably due to UV light generated by the introduction of Ar and He. This effect is seen on blanket but not on patterned wafers as the low-k is protected by the mask. He and Ar gas flows can both vary between 0 sccm and 500 sccm, whereby He+Ar total flow can go up to 1000 sccm.

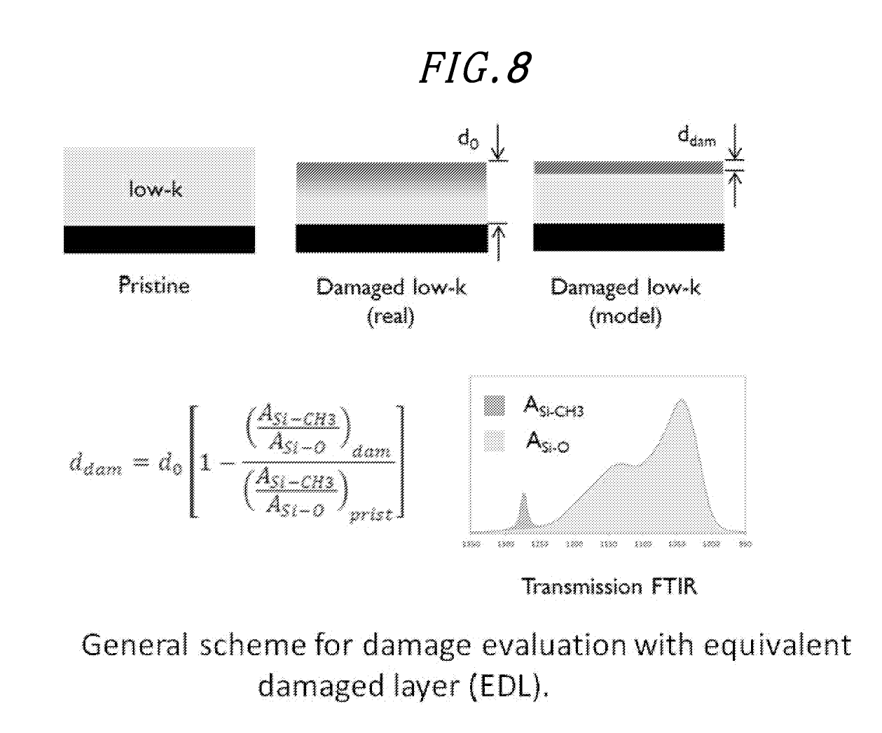

The calculation of values for the effective damage layer (EDL) is done by using the Si—CH₃ absorption peak area and the film thickness after etching, as shown in FIG. 8.

1. A method of etching a low-k material, characterized by etching the low-k material using a plasma of a mixture gas including NF₃ gas and a Clₓ-containing gas.

2. The method of claim 1, wherein a flow of the NF₃ gas is in a range between 5 sccm and 50 sccm.

3. The method of claim 1, wherein the Clₓ-containing gas is Cl₂ gas and a flow of the Cl₂ gas is larger than 0 sccm and is equal to or lower than 50 sccm.

4. The method of claim 1, wherein the low-k material is a porous organosilica low-k material.

5. The method of claim 1, wherein a pore size of the low-k material is in a range between 1 nm and 5 nm.

6. The method of claim 1, wherein the mixture gas further includes Ar gas, He gas, or a mixture of these.

7. The method of claim 1, wherein a dielectric hard mask is provided on the low-k material.
